(19) United States
(12) Patent Application Publication
(10) Pub. No.: US 2016/0322495 A1
(43) Pub. Date: Nov. 3, 2016

(54) SEMICONDUCTOR DEVICE AND METHOD OF MANUFACTURING THE SAME

(71) Applicant: Samsung Electronics Co., Ltd., Suwon-si (KR)

(72) Inventors: Kanghun Moon, lncheon (KR); JinBum Kim, Seoul (KR); Kwan Heum Lee, Suwon-si (KR); Choeun Lee, Pocheon-si (KR); Sujin Jung, Hwaseong-si (KR); Yang Xu, Hwaseong-si (KR)

(21) Appl. No.: 15/138,840

(22) Filed: Apr. 26, 2016

(30) Foreign Application Priority Data
Apr. 28, 2015 (KR) 10-2015-0059917

(51) Int. Cl. H01L 29/78; H01L 29/167; H01L 29/165; H01L 29/08; H01L 29/161

(52) U.S. Cl. CPC H01L 29/7848; H01L 29/0847; H01L 29/161; H01L 29/165; H01L 29/167; H01L 29/7851

(57) ABSTRACT

A semiconductor device includes an active pattern protruding from a substrate and extending in a first direction, first and second gate electrodes intersecting the active pattern in a second direction intersecting the first direction, and a source/drain region disposed on the active pattern between the first and second gate electrodes. The source/drain region includes a first part adjacent to an uppermost surface of the active pattern and provided at a level lower than the uppermost surface of the active pattern, and a second part disposed under the first part so as to be in contact with the first part. A width of the first part along the first direction decreases in a direction away from the substrate, and a width of the second part along the first direction increases in a direction away from the substrate.

### CROSS-REFERENCE TO RELATED APPLICATIONS

This U.S. non-provisional patent application claims priority under 35 U.S.C. §119 of Korean Patent Application No. 10-2015-0059917, filed on Apr. 28, 2015, the entire contents of which are hereby incorporated by reference.

### BACKGROUND

The inventive concept relates to a semiconductor device, and more particularly, to a fin field effect transistor (Fin FET) and a method of manufacturing the same.

A semiconductor device includes an integrated circuit having a metal-oxide-semiconductor field effect transistor (MOSFET). As a size and a design rule of the semiconductor device are gradually reduced, a scale down of the MOS FET is being accelerated. Since the scale down of the MOSFET may cause a short channel effect (SCE), the operating characteristic of the semiconductor device may be degraded.

### SUMMARY

Example embodiments of the inventive concept may provide a semiconductor device having an improved reliability. In one aspect, the semiconductor device may include a substrate, an active pattern protruding from the substrate and extending in a first direction, first and second gate electrodes intersecting the active pattern in a second direction intersecting the first direction and spaced apart from each other along the first direction, and a source/drain region disposed between the first and second gate electrodes and provided on the active pattern. The source/drain region may include a first part adjacent to an uppermost surface of the active pattern and provided at a level lower than the uppermost surface of the active pattern, and a second part being in contact with the first part and disposed under the first part. A width of the first part along the first direction may increasingly decrease in a direction away from the substrate, and a width of the second part along the first direction may gradually increase in a direction away from the substrate.

In some embodiments of the inventive concept, each of the first part and the second part may have the maximum thickness in a direction perpendicular to a top surface of the substrate. The maximum thickness of the first part may range from about 5% to about 15% of the sum of the maximum thicknesses of the first and second parts.

In some embodiments of the inventive concept, the maximum thickness of the first part may range from about 2 nm to about 8 nm.

In some embodiments of the inventive concept, at a contact point between a sidewall of the first part and the uppermost surface of the active pattern, an angle between the sidewall of the first part and the uppermost surface of the active pattern may be an acute angle.

In some embodiments of the inventive concept, the angle between the sidewall of the first part and the uppermost surface of the active pattern may range from 40 degrees to 60 degrees.

In some embodiments of the inventive concept, the second part may have a rounded bottom surface having a U-shape.

In some embodiments of the inventive concept, the source/drain region may include silicon-germanium (SiGe) doped with boron.

In some embodiments of the inventive concept, the active pattern may include a boron-doped region comprising boron. The boron-doped region may be adjacent to the uppermost surface of the active pattern and may be in contact with the first part.

In some embodiments of the inventive concept, a boron concentration of the boron-doped region may range from about 10¹⁴ atoms/cm³ to about 10¹⁵ atoms/cm³.

In some embodiments of the inventive concept, each of the boron-doped region and the first part may have the maximum thickness along a direction perpendicular to a top surface of the substrate. The maximum thickness of the first part may be equal to or greater than the maximum thickness of the boron doping region.

In some embodiments of the inventive concept, the boron-doped region may comprise a plurality of boron-doped regions. One of the boron-doped regions may be located between the source/drain region and the first gate electrode, another of the boron-doped regions may be located between the source/drain region and the second gate electrode.

In some embodiments of the inventive concept, a width of the boron-doped region may gradually increase in a direction away from the substrate.

In another aspect, the semiconductor device may include a substrate, an active pattern protruding from the substrate, extending in a first direction and having a recess region recessed from an uppermost surface of the active pattern, first and second gate electrodes intersecting the active pattern in a second direction intersecting the first direction and spaced apart from each other with the recess region interposed therebetween, and a source/drain region filling the recess region. The recess region may include a bottom surface, a pair of first inner walls connected to the uppermost surface of the active pattern, and a pair of second inner walls connected between the bottom surface and the pair of first inner walls. A width between the pair of first inner walls along the first direction may increase in a direction away from the uppermost surface of the active pattern. A width between the pair of second inner walls along the first direction may decrease in a direction away from the uppermost surface of the active pattern.

In some embodiments of the inventive concept, the bottom surface may have a rounded shape.

In some embodiments of the inventive concept, at a contact point between each of the first inner walls of the recess region and the uppermost surface of the active pattern, an angle between each of the first inner walls of the recess region and the uppermost surface of the active pattern may be an acute angle.

In some embodiments of the inventive concept, the angle between each of the first inner walls of the recess region and the uppermost surface of the active pattern may range from about 40 degrees to about 60 degrees.

In some embodiments of the inventive concept, the source/drain region may include a first source/drain layer conformally covering the first inner walls, the second inner walls and the bottom surface of the recess region, and a second source/drain layer located on the first source/drain layer to fill the recess region. The source/drain region may include SiGe doped with boron. A composition ratio of germanium (Ge) included in the second source/drain layer may be higher than a composition ratio of Ge included in the first source/drain layer.

In some embodiments of the inventive concept, the first source/drain layer may have a U-shape when viewed from a cross-sectional view.

In some embodiments of the inventive concept, the active pattern may include a pair of boron-doped regions. One of the pair of boron-doped regions may be provided between one of the pair of first inner walls and the first gate electrode, and the other of the pair of the boron-doped regions may be provided between the other of the pair of the first inner walls and the second gate electrode.

In some embodiments of the inventive concept, a width of each of the pair of boron doping regions along the first direction may increase in a direction away from the substrate.

It is noted that aspects described with respect to one embodiment may be incorporated in different embodiments although not specifically described relative thereto. That is, all embodiments and/or features of any embodiments can be combined in any way and/or combination. Moreover, other methods, systems, articles of manufacture, and/or devices according to embodiments of the inventive subject matter will be or become apparent to one with skill in the art upon review of the following drawings and detailed description. It is intended that all such additional systems, methods, articles of manufacture, and/or devices be included within this description, be within the scope of the present inventive subject matter, and be protected by the accompanying claims. It is further intended that all embodiments disclosed herein can be implemented separately or combined in any way and/or combination.

### BRIEF DESCRIPTION OF THE FIGURES

Example embodiments of the inventive concept will be described below in more detail with reference to the accompanying drawings. The embodiments of the inventive concept may, however, be embodied in different forms and should not be constructed as limited to the embodiments set forth herein. Rather, these embodiments are provided so that this disclosure will be thorough and complete, and will fully convey the scope of the inventive concept to those skilled in the art. Like numbers refer to like elements throughout.

FIG. 1A is a perspective view illustrating a semiconductor device in accordance with example embodiments of the inventive concept.

FIG. 1B illustrates cross-sectional views taken along the lines I-I′, II-II′, and III-III′ of FIG. 1A.

FIG. 1C is an enlarged cross-sectional view of a portion ‘A’ of FIG. 1B.

FIGS. 2A through 9A are perspective views illustrating a method of manufacturing a semiconductor device in accordance with example embodiments of the inventive concept.

FIGS. 2B through 9B are cross-sectional views taken along the lines I-I′, II-II′, and III-III′ of FIGS. 2A through 9A, respectively.

FIG. 6C is an enlarged cross-sectional view of a portion ‘B’ of FIG. 6B.

FIG. 10 is a schematic block diagram illustrating an electronic system including a semiconductor device in accordance with example embodiments of the inventive concept.

FIG. 11 is a schematic block diagram illustrating an electronic device including a semiconductor device in accordance with example embodiments of the inventive concept.

FIG. 12 is an equivalent circuit illustrating a static random access memory (SRAM) cell in accordance with example embodiments of the inventive concept.

FIGS. 13 through 15 illustrate examples of a multimedia device including a semiconductor device in accordance with example embodiments of the inventive concept.

### DETAILED DESCRIPTION

Embodiments of inventive concepts will be described more fully hereinafter with reference to the accompanying drawings, in which embodiments of the invention are shown. This inventive concept may, however, be embodied in many different forms and should not be construed as limited to the embodiments set forth herein. Rather, these embodiments are provided so that this disclosure will be thorough and complete, and will fully convey the scope of the inventive concept to those skilled in the art. In the drawings, the size and relative sizes of layers and regions may be exaggerated for clarity. Like numbers refer to like elements throughout the specification.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments of the inventive concept may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

The thicknesses of layers and regions in the drawings may be exaggerated for the sake of clarity. Further, it will be understood that when a layer is referred to as being “on” another layer or a substrate, the layer may be formed directly on the other layer or the substrate, or there may be an intervening layer therebetween.

Terms such as “top,” “bottom,” “upper,” “lower,” “above,” “below,” and the like are used herein to describe the relative positions of elements or features. For example, when an upper part of a drawing is referred to as a “top” and a lower part of a drawing is referred to as a “bottom” for the sake of convenience, in practice, the “top” may also be called a “bottom” and the “bottom” may also be a “top” without departing from the teachings of the inventive concept.

Furthermore, throughout this disclosure, directional terms such as “upper,” “intermediate,” “lower,” and the like may be used herein to describe the relationship of one element or feature with another, and the inventive concept should not be limited by these terms. Accordingly, these terms such as “upper,” “intermediate,” “lower,” and the like may be replaced by other terms such as “first,” “second,” “third,” and the like to describe the elements and features.

It will be understood that, although the terms “first,” “second,” etc. may be used herein to describe various elements, these elements should not be limited by these terms. These terms are only used to distinguish one element from another. Thus, a first element could be termed a second element without departing from the teachings of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

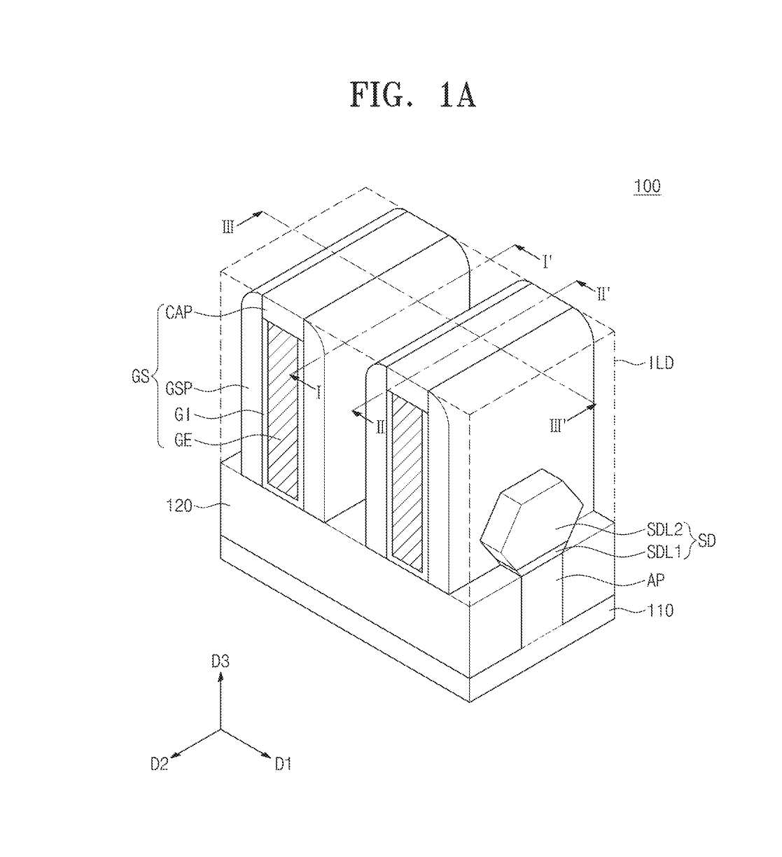

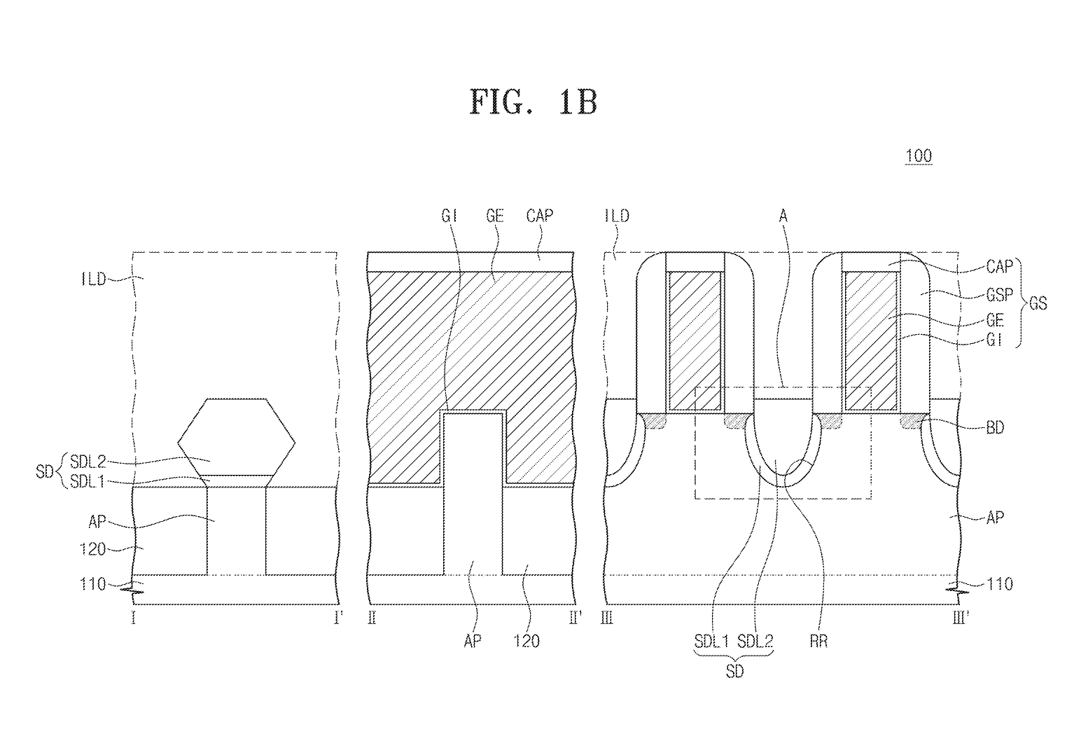

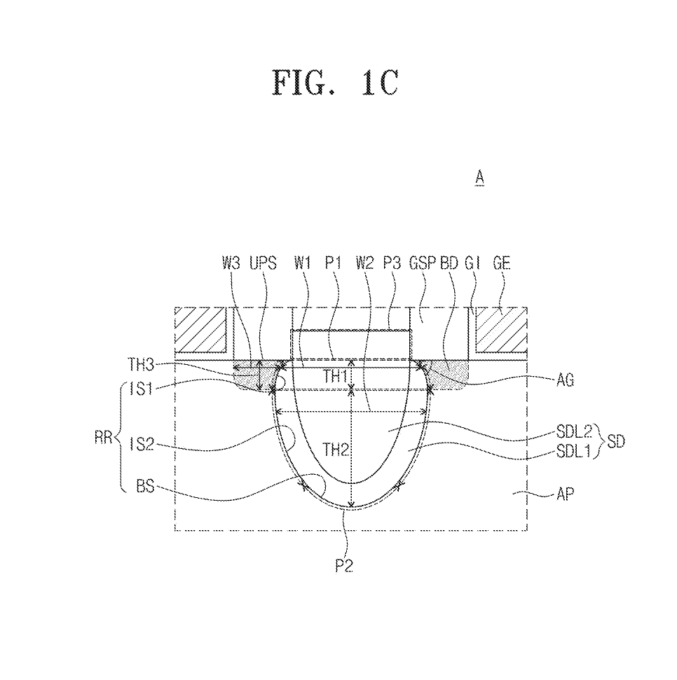

FIG. 1A is a perspective view illustrating a semiconductor device in accordance with example embodiments of the inventive concept. FIG. 1B illustrates cross-sectional views taken along the lines I-I′, II-II′, and III-III′ of FIG. 1A. FIG. 1C is an enlarged cross-sectional view of a portion ‘A’ of FIG. 1B.

Referring to FIGS. 1A, 1B and 1C, a semiconductor device 100 may include a substrate 110, an active pattern AP, gate structures GS and source/drain regions SD.

The substrate 110 may be a semiconductor substrate. For example, the substrate 110 may be a single-crystalline silicon substrate, a silicon-on-insulator (SOI) substrate, or an epitaxial silicon layer obtained by performing a selective epitaxial growth (SEG) process.

The active pattern AP may be provided on the substrate 110. The active pattern AP may extend in a first direction D1. The active pattern AP may protrude from the substrate 110 along a third direction D3 that is perpendicular to the first direction D1 and a second direction D2 intersecting (e.g., perpendicular to) the first direction D1. The active pattern AP may include the same material as the substrate 110 but is not limited thereto.

According to some embodiments of the inventive concept, a buffer layer (not illustrated) may be further provided between the substrate 110 and the active pattern AP. The buffer layer may have the same lattice structure as the active pattern AP but may have a different lattice constant from the active pattern AP. Accordingly, a strain may be applied to the active pattern AP by the buffer layer. According to some embodiments of the inventive concept, the buffer layer may be omitted.

Device isolation patterns 120 may be provided at opposite sides of the active pattern AP. The device isolation patterns 120 may be provided on the substrate 110 to extend along the first direction D1. The device isolation patterns 120 may be separated from each other along the second direction D2 with the active pattern AP interposed therebetween. The device isolation patterns 120 may expose an upper portion of the active pattern AP. In other words, a top surface and portions of sidewall of the active pattern AP may be exposed by the device isolation patterns 120. The device isolation patterns 120 may include, for example, silicon oxide, silicon nitride and/or silicon oxynitride.

Gate structures GS may be provided on the substrate 110. The gate structures GS may extend in the second direction D2 to intersect the active pattern AP and may be separated from one another in the first direction D1. In other words, each gate structure GS may cover the exposed top surface and sidewalls of the active pattern AP and may extend on top surfaces of the device isolation patterns 120. The exposed upper portion of the active pattern AP may function as a channel region of a transistor including the active pattern AP, the gate structure GS and the source/drain regions SD. According to an embodiment of the inventive concept, the transistor may be a P-type MOSFET (PMOSFET).

Each gate structure GS may include a gate electrode GE extending in the second direction D2, a gate insulating pattern GI disposed between the gate electrode GE and the active pattern AP, a capping pattern CAP covering a top surface of the gate electrode GE, and gate spacers GSP provided on both sidewalls of the gate electrode GE. The gate insulating pattern GI may extend into between the gate electrode GE and the device isolation patterns 120 and between the gate electrode GE and the gate spacers GSP.

The gate electrode GE may include at least one of a conductive metallic nitride (e.g., titanium nitride, tantalum nitride, etc.) or a metal (e.g., aluminum, tungsten, copper, etc.). The gate insulating pattern GI may include at least one of high dielectric layers (e.g., hafnium oxide, hafnium silicate, zirconium oxide and zirconium silicate). The capping pattern CAP and the gate spacers GSP may include, for example, silicon oxide, silicon nitride and/or silicon oxynitride.

The active pattern AP may include a recess region RR that is formed between the gate electrodes GE. The recess region RR may include a pair of first inner walls IS1 separated from each other in the first direction D1, a pair of second inner walls IS2 separated from each other in the first direction D1, and a bottom surface BS. The pair of first inner walls IS1 may be connected between uppermost surfaces of the active pattern AP and the pair of second inner walls IS2, and the pair of second inner walls IS2 may be connected between the bottom surface BS and the pair of first inner walls IS1.

A width W1 between the pair of first inner walls IS1 along the first direction D1 may increase in a direction away from the uppermost surface UPS of the active pattern AP. When viewed from a plan view, the first inner walls IS1 may overlap the gate spacers GSP. An angel AG between each of the first inner walls IS1 and the uppermost surface UPS of the active pattern AP may be an acute angle at a contact point between each of the first inner walls IS1 and the uppermost surface UPS of the active pattern AP. For example, the acute angle AG may range from 40 degrees through 60 degrees. A width W2 between the pair of second inner walls IS2 along the first direction D1 may decrease in a direction away from the uppermost surface UPS of the active pattern AP. The bottom surface BS may have a rounded shape.

The active pattern AP may include a boron-doped region BD that is located between each gate electrode GE and the recess region RR and is adjacent to the uppermost surface UPS of the active pattern AP. A pair of the boron-doped regions BD may be separated from each other in the first direction D1 with the recess region RR interposed therebetween. The boron-doped regions BD may overlap the gate spacers GSP in a plan view, respectively. One sidewall of each boron-doped region BD may be exposed by the recess region RR. In an embodiment, the one sidewall of each of the boron-doped regions BD may be in contact with the each of the first inner walls IS1. That is, the one sidewall of each of the boron-doped region BD may be a part of the each of the first inner walls IS1. A width W3 of each of the boron-doped regions BD along the first direction D1 may decrease in a direction away from the uppermost surface UPS of the active pattern AP. In other words, the width W3 of each boron-doped region BD along the first direction D1 may increase in a direction away from the substrate 110.

Each boron-doped region BD may have a boron concentration greater than that of other part of the active pattern AP. For example, the boron concentration of the boron-doped regions BD may range from 10¹⁴ atoms/cm³ to 10¹⁵ atoms/cm³.

The source/drain region SD may be provided between the gate electrodes GE to fill the recess region RR. The source/drain region SD may include silicon-germanium (SiGe) doped with boron. A concentration of boron contained in the source/drain region SD may range from 10²⁰ atoms/cm³ to 10²¹ atoms/cm³.

The source/drain region SD may include first and second source/drain parts P1 and P2 provided at a level lower than the uppermost surface UPS of the active pattern AP. In some embodiments, the source/drain region SD may further include a third source/drain part P3 which is provided at a level higher than the uppermost surface UPS of the active pattern AP and is in contact with the first source/drain part P1. The first source/drain part P1 may be a part of the source/drain region SD which is adjacent to the uppermost surface UPS of the active pattern AP while being located at a level lower than the uppermost surface UPS of the active pattern AP. The second source/drain part P2 may be a part of the source/drain region SD which is located below the first source/drain part P1. The first source/drain part P1 and the second source/drain part P2 may be parts of the source/drain region SD of one body. Sidewalls of the first source/drain part P1 may be in contact with the first inner walls IS1 of the recess region RR, respectively, and sidewalls of the second source/drain part P2 may be in contact with the second inner walls IS2 of the recess region RR, respectively. Accordingly, the width W1 of the first source/drain part P1 along the first direction D1 may decrease in a direction away from the substrate 110, and the width W2 of the second source/drain part P2 along the first direction D1 may increase in a direction away from the substrate 110. An angle AG between each of the sidewalls, being in contact with the first inner walls IS1, of the first source/drain part P1 and the uppermost surface UPS of the active pattern AP may be an acute angle and may range, for example, from 40 degrees to 60 degrees. A bottom surface of the second source/drain part P2 may be in contact with the bottom surface BS of the recess region RR, so the bottom surface of the second source/drain part P2 may have a rounded shape of a U-shape. The first source/drain part P1 may have a first maximum thickness TH1 in the third direction D3 perpendicular to the top surface of the substrate 110, and the second source/drain part P2 may have a second maximum thickness TH2 in the third direction D3. A sum of the first and second maximum thicknesses TH1 and TH2 may be equal to a depth of the recess region RR. The first maximum thickness TH1 may range from about 5% to about 15% of the sum of the first and second maximum thicknesses TH1 and TH2. For example, the first maximum thickness TH1 may be in a range of 2 nm to 8 nm. Further, the first maximum thickness TH1 may be equal to or greater than a maximum thickness TH3 of the boron-doped region BD along the third direction D3 perpendicular to the top surface of the substrate 110.

In another view, the source/drain region SD may include first and second source/drain layers SDL1 and SDL2. The first source/drain layer SDL1 may conformally cover the first inner walls IS1, the second inner walls IS2 and the bottom surface BS of the recess region RR. The second source/drain layer SDL2 may be disposed on the first source/drain layer SDL1 to fill the recess region RR. According to some embodiments, the second source/drain layer SDL2 may extend between the gate electrodes GE and may partially cover sidewalls of the gate spacers GSP. In a cross-sectional view defined by the first and third directions D1 and D3 (Refer to FIG. 1C), the first source/drain layer SDL1 may have a U-shaped cross section. Further, the first source/drain layer SDL1 may extend in the second direction D2 while maintaining the U-shaped cross section. That is, the first source/drain layer SDL1 may have a horseshoe-shape of which the U-shaped cross section extends in the second direction D2. The first and second source/drain layers SDL1 and SDL2 may include SiGe, and a composition ratio of germanium (Ge) contained in the second source/drain layer SDL2 may be greater than a composition ratio of Ge contained in the first source/drain layer SDL1. For example, the germanium composition ratio of SiGe contained in the first source/drain layer SDL1 may range from 10 at % to 30 at %, and the germanium composition ratio of SiGe contained in the second source/drain layer SDL2 may range from 40 at % to 60 at %. Accordingly, a lattice constant of the first source/drain layer SDL1 may be greater than a lattice constant of the active pattern AP, and a lattice constant of the second source/drain layer SDL2 may be greater than the lattice constant of the first source/drain layer SDL1. Consequently, a compressive strain may be applied to the active pattern AP below the gate electrode GE that can function as a channel region of a transistor including the active pattern AP, the gate structure GS and the source/drain regions SD.

A lower interlayer insulating layer ILD covering the source/drain regions SD may be provided on the substrate 110. The lower interlayer insulating layer ILD may include at least one of a silicon oxide layer, a silicon nitride layer, a silicon oxynitride layer, or a low-k dielectric layer.

Although not illustrated in the drawings, an upper interlayer insulating layer may be provided on the substrate 110 including the gate structure GS. The upper interlayer insulating layer may include an oxide, a nitride, and/or an oxynitride. First contact plugs may penetrate the upper interlayer insulating layer and the lower interlayer insulating layer ILD so as to be electrically connected to the source/drain regions SD, and a second contact plug may penetrate the upper interlayer insulating layer and the lower interlayer insulating layer ILD so as to be electrically connected to the gate electrode GE. Interconnection lines may be disposed on the upper interlayer insulating layer so as to be connected to the first and second contact plugs. Voltages may be applied to the source/drain regions SD and the gate electrode GE through the interconnection lines and the first and second contact plugs. The first and second contact plugs and the interconnection lines may include a conductive material.

In the semiconductor device 100 according to some embodiments of the inventive concepts, the recess region RR of the active pattern AP may include the first inner walls IS1 which are connected to the uppermost surfaces UPS of the active pattern AP and of which the width W1 along the first direction D1 increases in a direction away the uppermost surface UPS of the active pattern AP. The angle AG between each of the first inner walls IS1 and the uppermost surface UPS of the active pattern AP may be the acute angle at the contact point between each of the first inner walls IS1 of the recess region RR and the uppermost surface UPS of the active pattern AP. Through the first inner walls IS1 contacting end portions of the first source/drain layer SDL1, it is possible to inhibit end portions of the first source/drain layer SDL1 from being grown with a (111) plane. As a result, the source/drain regions SD of the semiconductor device 100 may not include boron segregation caused by the (111) plane and defects caused by the boron segregation, and thereby to improve reliability of the semiconductor device 100.

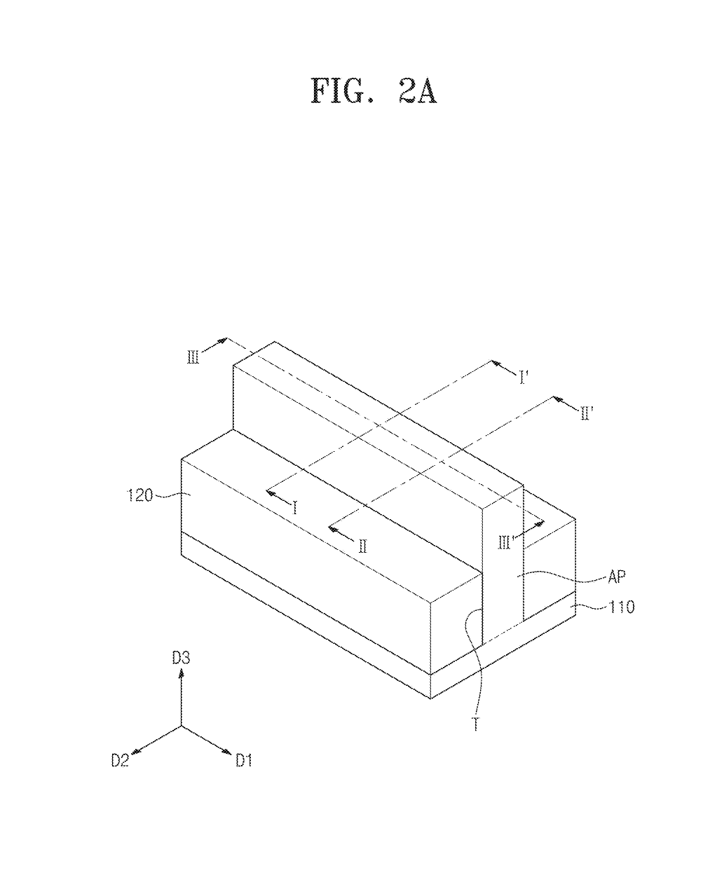

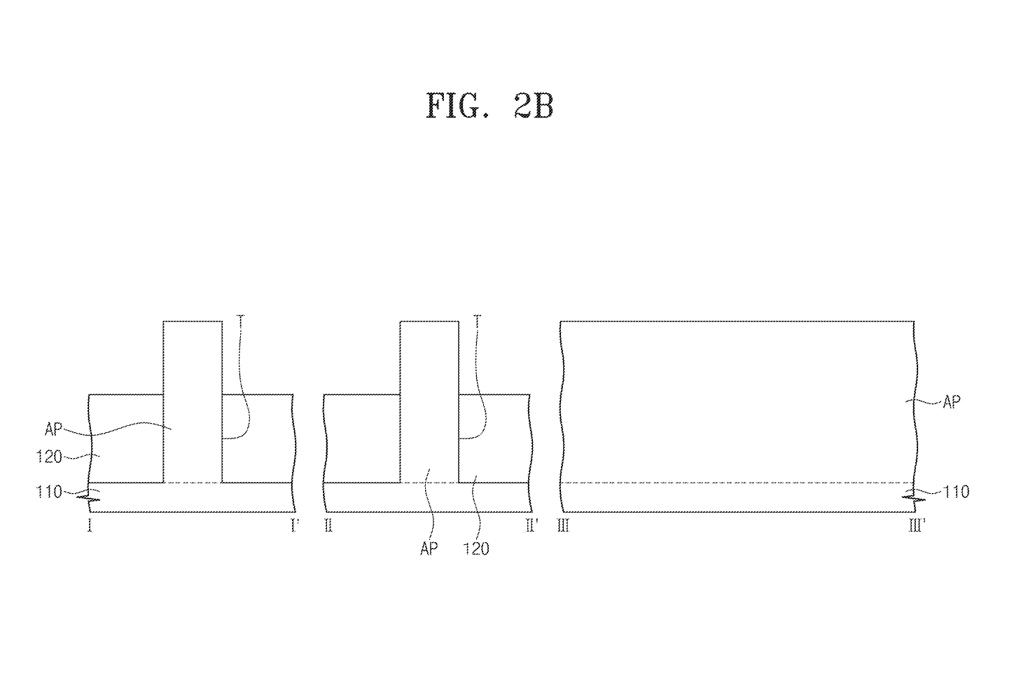

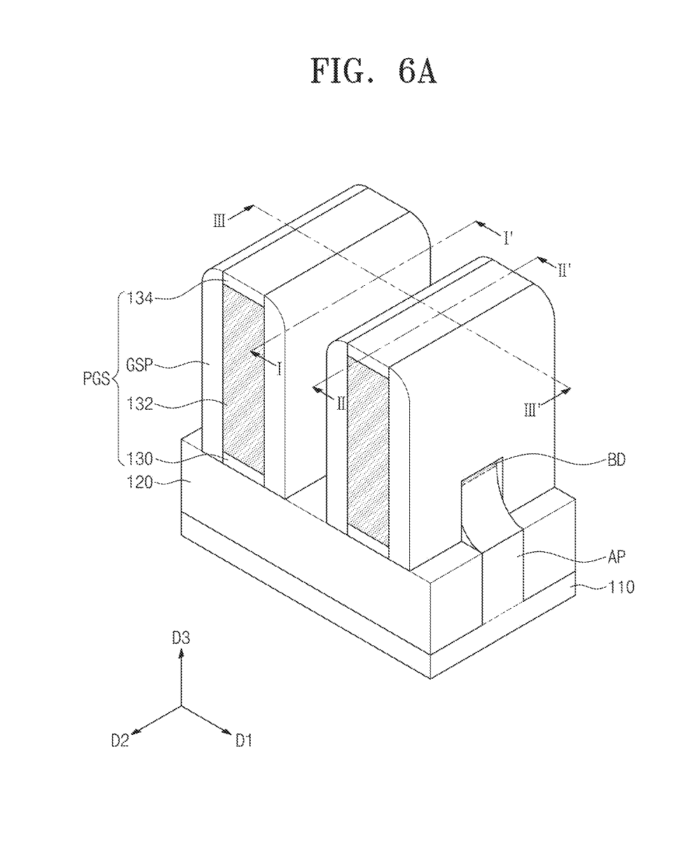

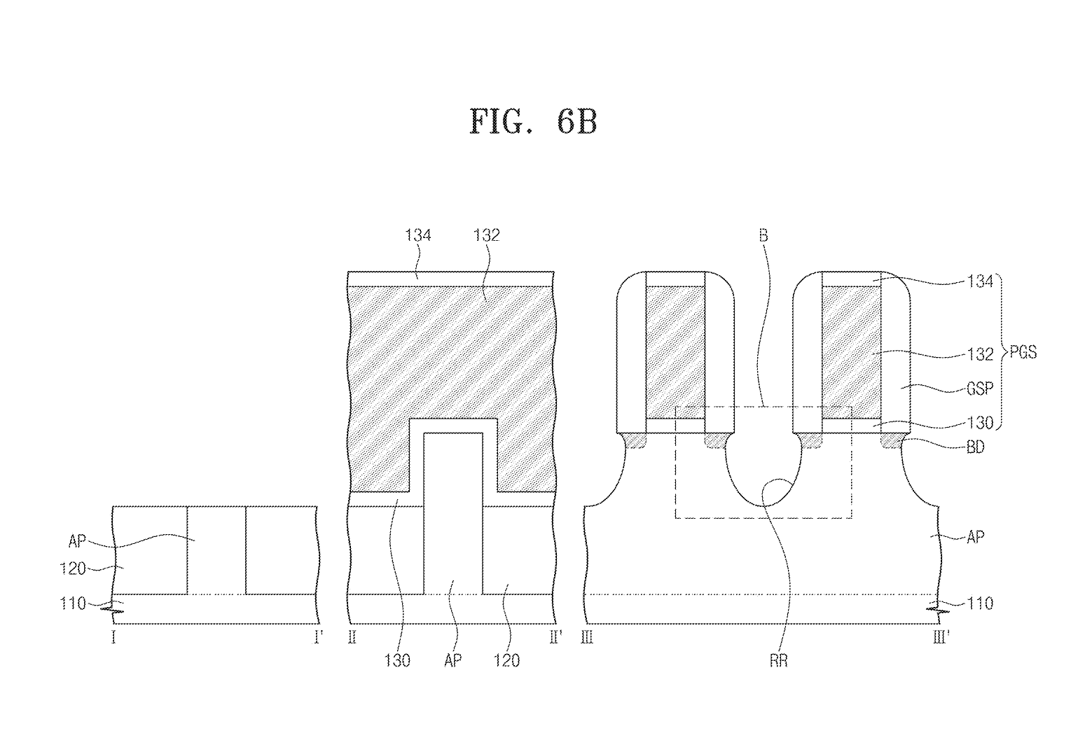

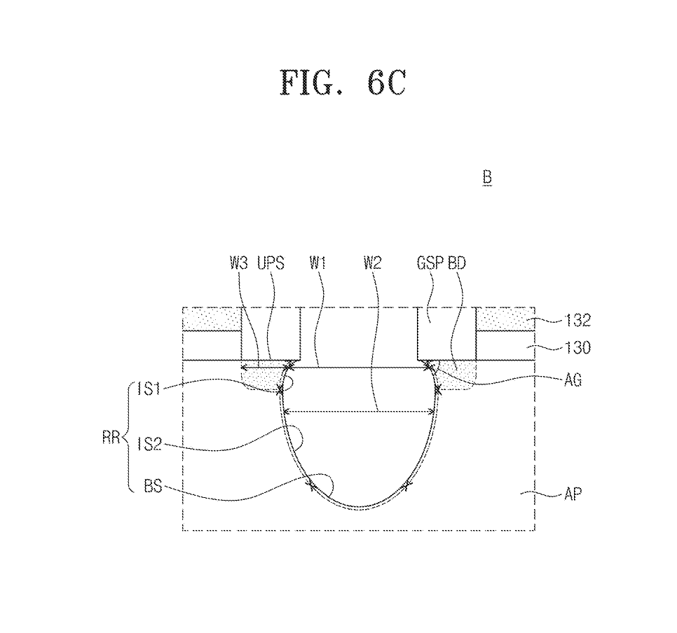

FIGS. 2A through 9A are perspective views illustrating a method of manufacturing a semiconductor device in accordance with example embodiments of the inventive concept. FIGS. 2B through 9B are cross-sectional views taken along the lines I-I′, II-II′, and III-III′ of FIGS. 2A through 9A, respectively. FIG. 6C is an enlarged cross-sectional view of a portion ‘B’ of FIG. 6B. Hereinafter, the same elements as described with reference to FIGS. 1A, 1B, and 1C will be indicated by the same reference numerals or the same reference designators. For the purpose of ease and convenience in explanation, the same descriptions as mentioned with reference to FIGS. 1A, 1B, and 1C will omitted or mentioned briefly.

Referring to FIGS. 2A and 2B, the active pattern AP may be formed on the substrate 110. The substrate 110 may be a semiconductor substrate. For example, the substrate 110 may be a single-crystalline silicon substrate, a silicon-on-insulator (SOI) substrate, or an epitaxial silicon layer obtained by performing a selective epitaxial growth (SEG) process.

The active pattern AP may protrude from the substrate 110 and may extend along the first direction D1. Forming the active pattern AP may include pattering the substrate 110 to form trenches T defining the active pattern AP. Forming the trenches T may include forming a mask pattern (not illustrated) defining a region in which the active pattern AP is to be formed on the substrate 110, and anisotropically etching the substrate 110 using the mask pattern as an etching mask.

Device isolation patterns 120 may be formed at opposite sides of the active pattern AP. The device isolation patterns 120 may partially fill the trenches T. forming the device isolation patterns 120 may include forming an insulating layer (not illustrated) filling the trenches T on the substrate 110, planarizing the insulating layer until the mask pattern is exposed, and recessing an upper portion of the planarized insulating layer to expose an upper portion of the active pattern AP. The mask pattern may be removed while the upper portion of the planarized insulating layer is recessed.

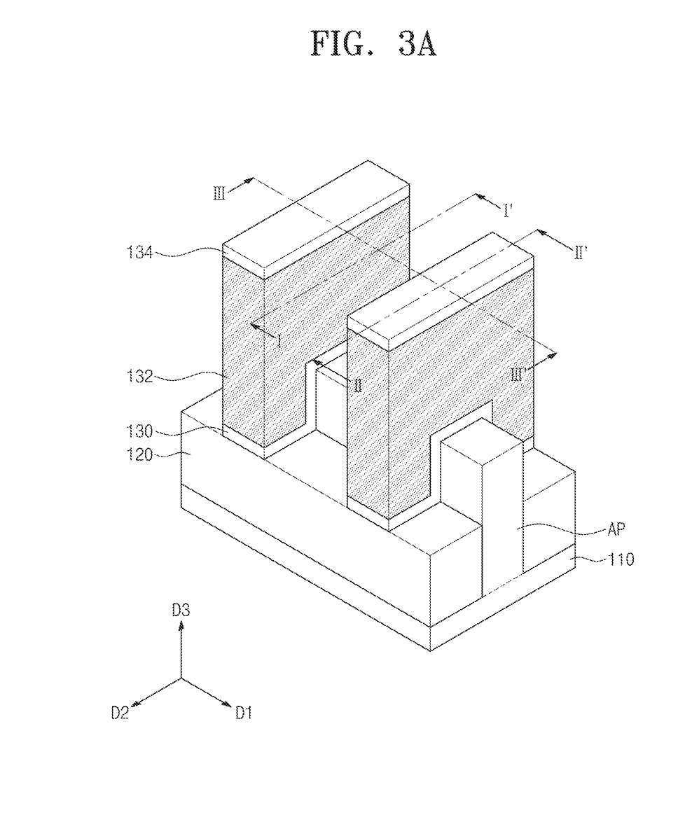

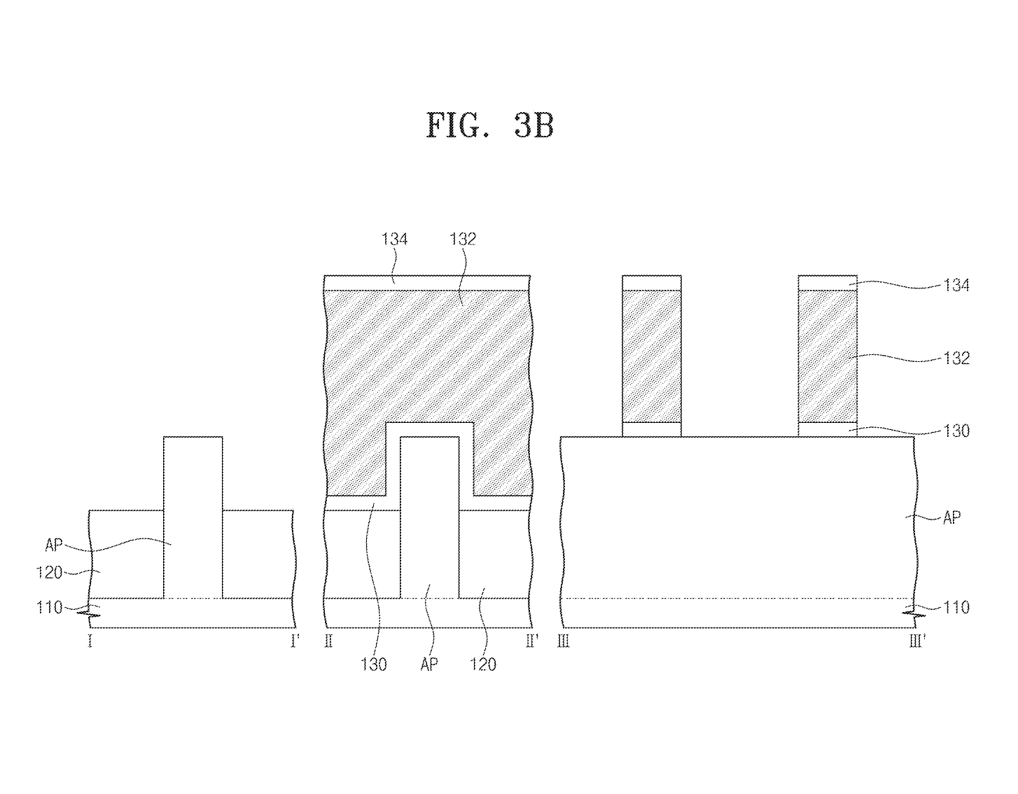

Referring to FIGS. 3A and 3B, an etch stop layer (not illustrated) and a sacrificial gate layer (not illustrated) covering the active pattern AP and the device isolation patterns 120 may be sequentially formed on the substrate 110. The etch stop layer may include, for example, a silicon oxide layer. The sacrificial gate layer may include a material having an etch selectivity with respect to the etch stop layer. For example, the sacrificial gate layer may include poly-silicon.

The sacrificial gate layer may be patterned to form sacrificial gate patterns 132. Forming the sacrificial gate patterns 132 may include forming gate mask patterns 134 on the sacrificial gate layer, and etching the sacrificial gate layer using the gate mask patterns 134 as an etching mask. The gate mask patterns 134 may include, for example, silicon nitride. Etching the sacrificial gate layer may include performing an etching process having an etch selectivity with respect to the etch stop layer. The gate mask patterns 134 may extend in the second direction D2 intersecting the first direction D1 and may be spaced apart from one another along the first direction D1. Accordingly, the sacrificial gate patterns 132 may also extend in the second direction D2 intersecting the first direction D1 and may be spaced apart from one another along the first direction D1.

The etch stop layer disposed at opposite sides of each of the sacrificial gate patterns 132 may be removed to form etch stop patterns 130 under the sacrificial gate patterns 132. Each of the etch stop patterns 130 may extend in the second direction D2 along a bottom surface of each of the sacrificial gate patterns 132 and may cover a top surface and sidewalls of the active pattern AP exposed by the device isolation patterns 120 and top surfaces of the device isolation patterns 120. The etch stop patterns 130 may be spaced apart from one another along the first direction D1, and an upper portion of the active pattern AP may be exposed between the etch stop patterns 130.

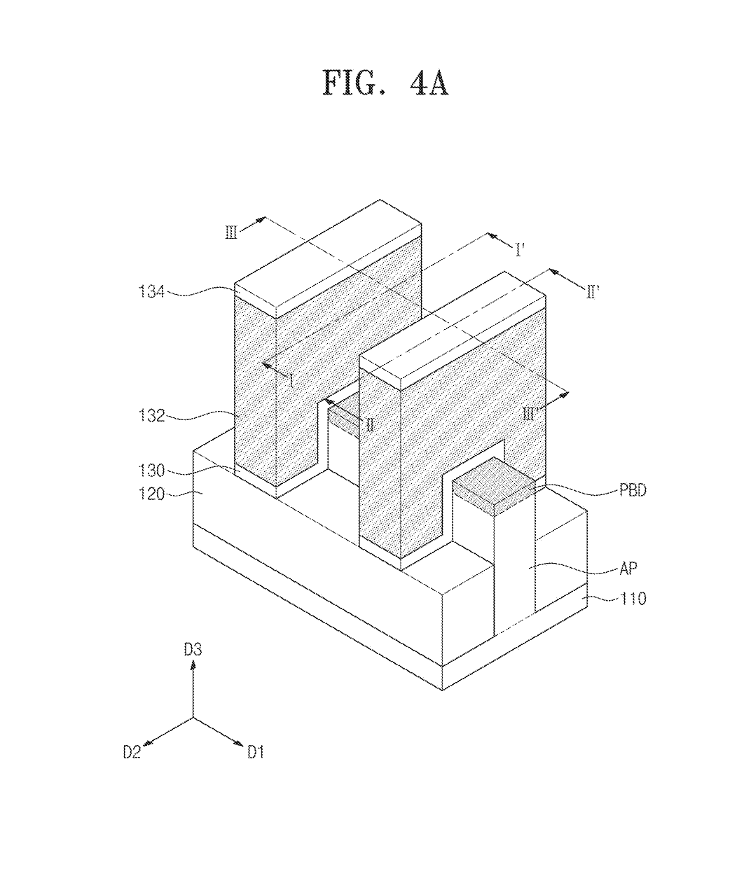

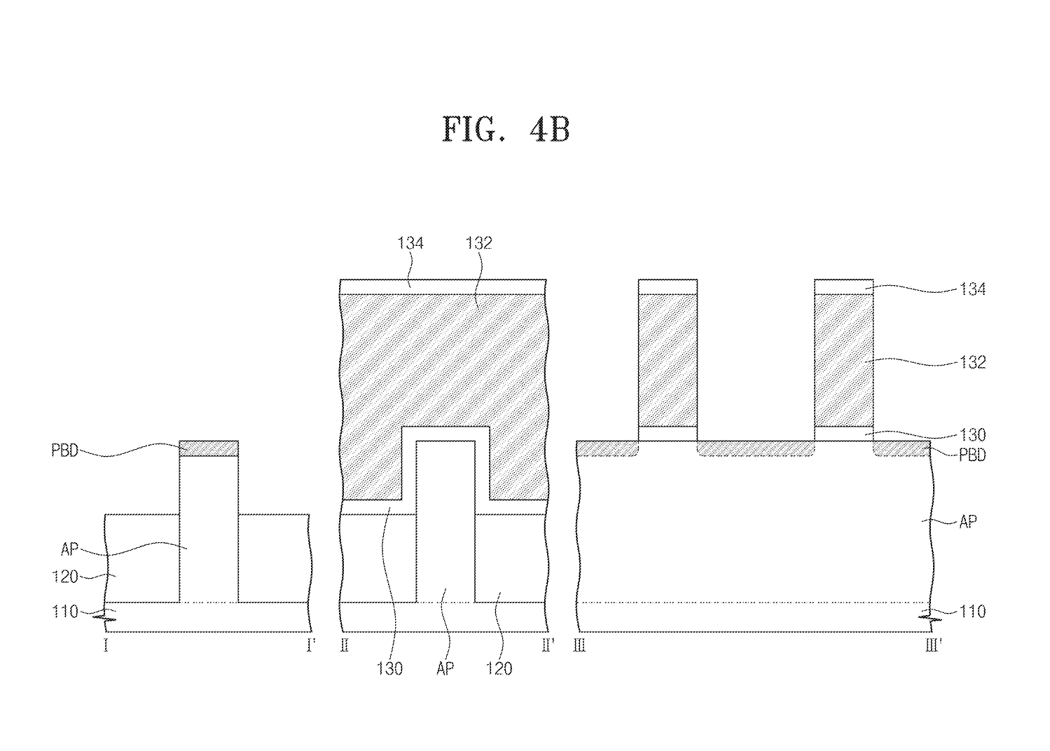

Referring to FIGS. 4A and 4B, preliminary boron-doped regions PBD may be formed in the upper portions of the active pattern AP exposed by the etch stop patterns 130. Forming the preliminary boron-doped regions PBD may include doping the upper portions of the active pattern AP with boron, using the etch stop patterns 130, the sacrificial gate patterns 132 and the gate mask patterns 134 as a mask. Doping the upper portions of the active pattern AP with boron may be performed using an ion implantation method. For example, the preliminary boron-doped regions PBD may be partially formed in the upper portions of the active pattern AP exposed by the etch stop patterns 130. That is, the preliminary boron-doped regions PBD may be formed to have a predetermined depth from a top surface of the active pattern AP exposed by the etch stop patterns 130. For example, a boron concentration of the preliminary boron-doped regions PBD may range from 10¹⁴ atoms/cm³ to 10¹⁵ atoms/cm³.

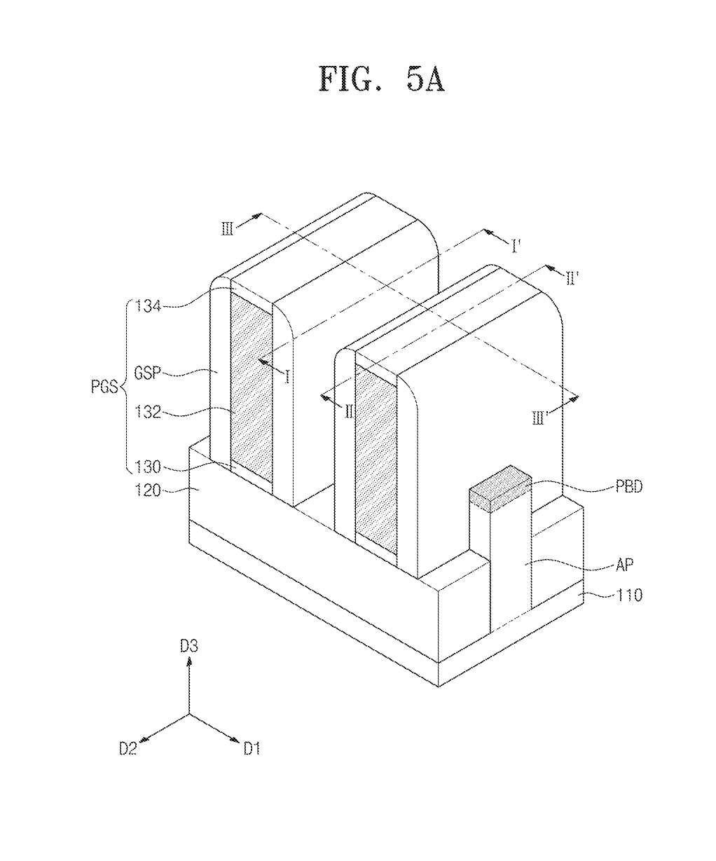

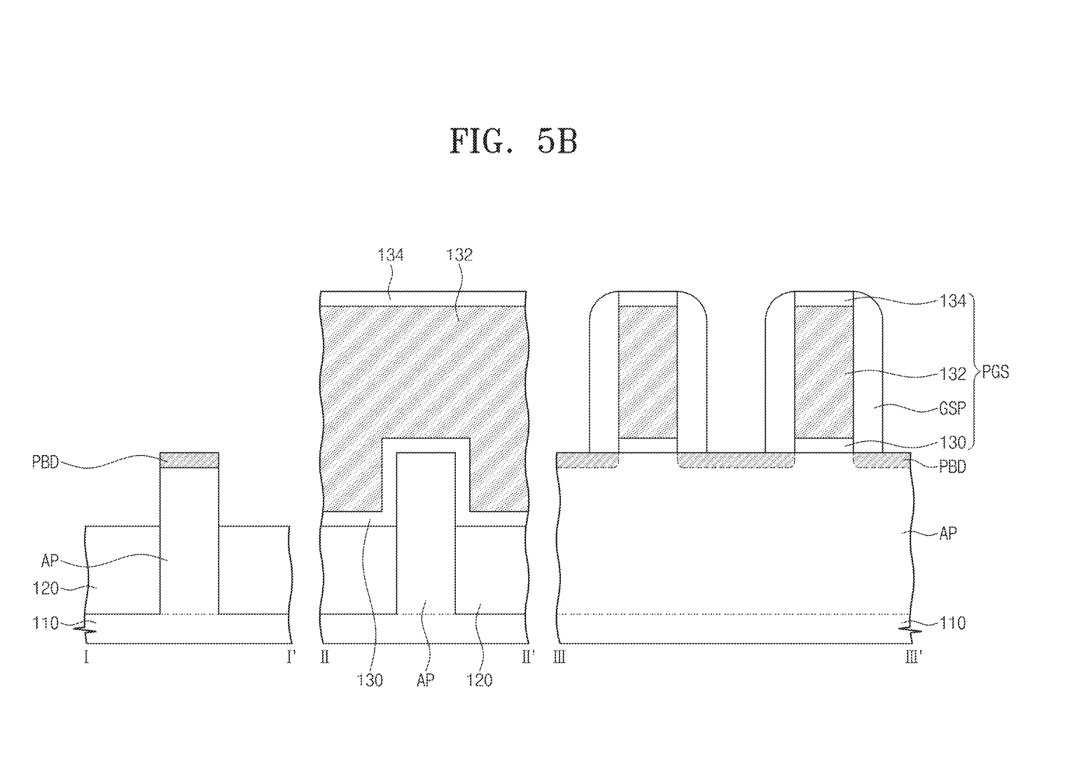

Referring to FIGS. 5A and 5B, gate spacers GSP may be formed on both sidewalls of the sacrificial gate patterns 132. Forming the gate spacers GSP may include forming a gate spacer layer on the substrate 110 including the sacrificial gate patterns 132 and anisotropically etching the gate spacer layer. The gate spacers GSP may be formed, so preliminary gate structures PGS may be defined. Each of the preliminary gate structures PGS may include the etch stop pattern 130, the sacrificial gate pattern 132, the gate mask pattern 134 and a pair of the gate spacers GSP formed on both sidewalls of the sacrificial gate pattern 132. The etch stop pattern 130, the sacrificial gate pattern 132, and the gate mask pattern 134 may be sequentially stacked in each of the preliminary gate structure PGS. The active pattern AP and the preliminary boron-doped region PBD formed in the upper portion of the active pattern AP may be exposed between the preliminary gate structures PGS.

Referring to FIGS. 6A, 6B and 6C, a recess region RR may be formed in the active pattern AP exposed by the preliminary gate structures PGS. Forming the recess region RR may include isotropically etching the active pattern AP using the preliminary gate structures PGS as an etching mask. During the isotropic etching process, an etch rate of the rest portion, not doped with boron, of the active pattern AP may be greater than that of the preliminary boron-doped regions (PBD of FIGS. 5A and 5B). For example, the isotropic etching process may be performed by a dry etching process using at least one of a CF₃ gas, a Cl₂ gas, a NF₃ gas and a HBr gas.

The recess region RR formed by the isotropic etching process may include a pair of first inner walls IS1 spaced apart from each other along the first direction D1, a pair of second inner walls IS2 spaced apart from each other along the first direction D1, and a bottom surface BS. The pair of the first inner walls IS1 may be connected between the uppermost surfaces UPS of the active pattern AP and the pair of second inner walls IS2. The pair of the second inner walls IS2 may be connected between the bottom surface BS and the pair of the first inner walls IS1. A width W1 between the pair of the first inner walls IS1 in the first direction D1 may increase in a direction away from the uppermost surface UPS of the active pattern AP. In a plan view, the first inner walls IS1 may overlap the gate spacers GSP. At a contact point between each of the first inner walls IS1 and the uppermost surface UPS of the active pattern AP, an angle AG between each of the first inner walls IS1 and the uppermost surface UPS of the active pattern AP may be an acute angle. For example, the angle AG may range from 40 degrees to 60 degrees. A width W2 between the pair of the second inner walls IS2 in the first direction D1 may decrease in a direction away from the uppermost surface UPS of the active pattern AP. The bottom surface BS may have a rounded shape.

By the isotropic etching process, one preliminary boron-doped region (PBD of FIGS. 5A and 5B) may be divided into a pair of boron-doped regions BD spaced apart from each other along the first direction D1. The boron-doped regions BD may overlap the gate spacers GSP in a plan view. One sidewall of each boron-doped region BD may be exposed by the recess region RR. The one sidewall of each boron-doped region BD may be in contact with the each of the first inner walls IS1. That is, the one sidewall of each boron-doped region BD may be a part of each of the first inner walls IS1. A width W3 of each boron-doped region BD along the first direction D1 may decrease in a direction away from the uppermost surface UPS of the active pattern AP. That is, the width W3 of each boron-doped region BD along the first direction D1 may increase in a direction away from the substrate 110.

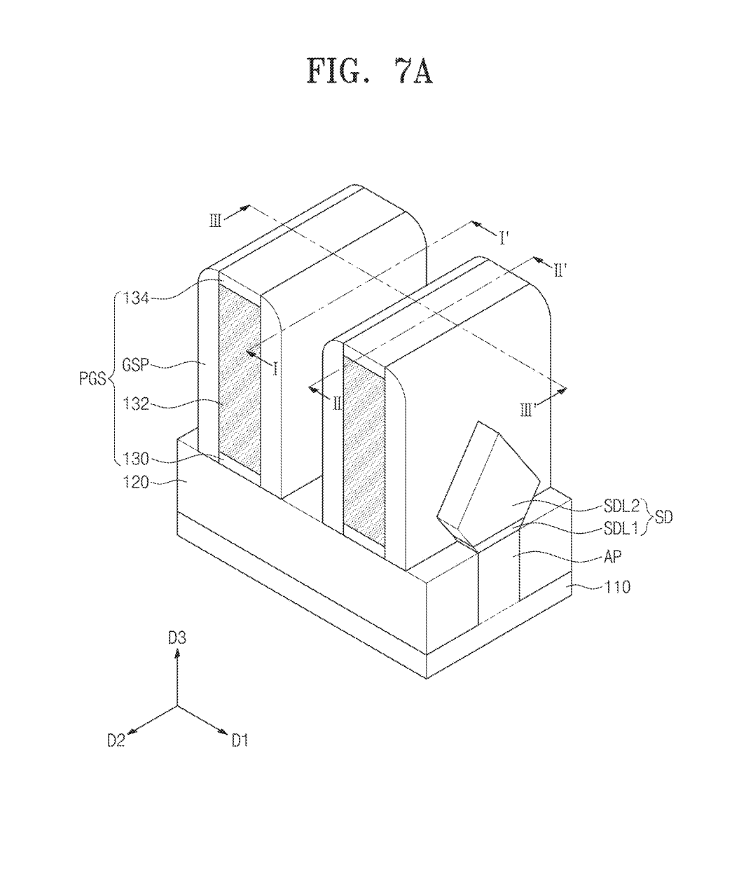

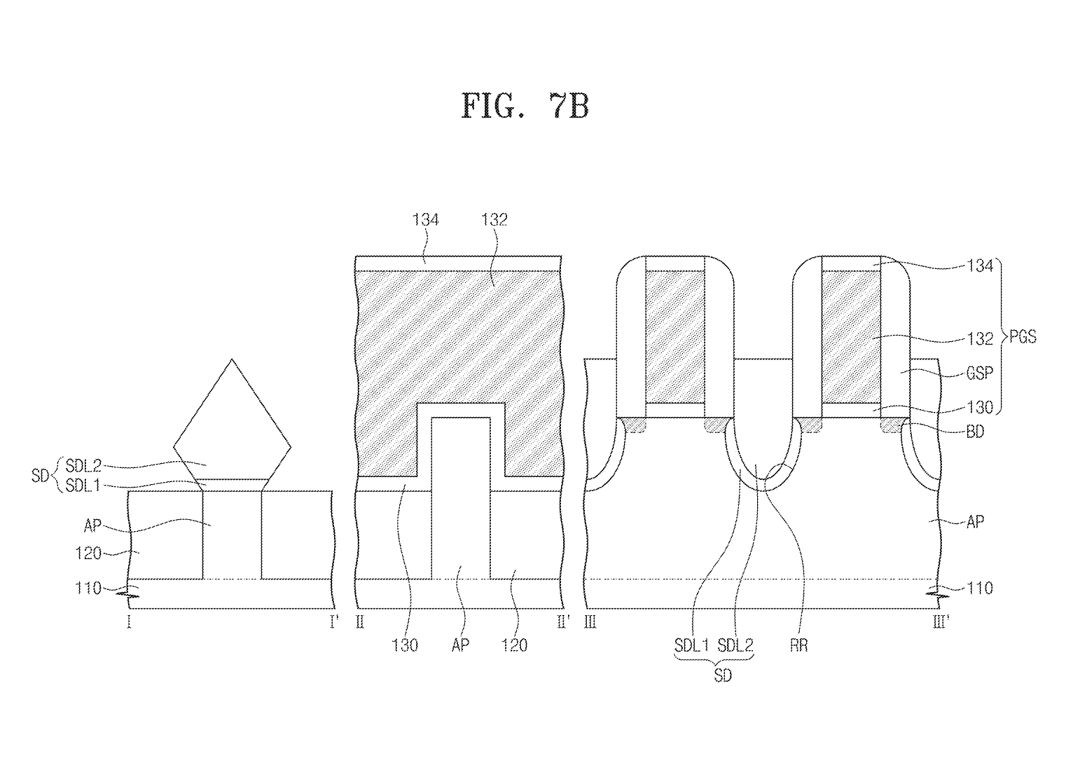

Referring to FIGS. 7A and 7B, a source/drain region SD filling the recess region RR may be formed. The source/drain region SD may include a first source/drain layer SDL1 and a second source/drain layer SDL2.

Forming the source/drain region SD may include performing a selective epitaxial growth (SEG) process on the substrate 110. The first source/drain layer SDL1 and the second source/drain layer SDL2 may be sequentially formed by performing the selective epitaxial growth (SEG) process. The first source/drain layer SDL1 may include an epitaxial layer grown using the first inner walls IS1, the second inner walls IS2 and the bottom surface BS of the recess region RR as a seed. The second source/drain layer SDL2 may include an epitaxial layer grown from the first source/drain layer SDL1. The first and second source/drain layers SDL1 and SDL2 may include SiGe, and a composition ratio of Ge contained in the second source/drain layer SDL2 may be greater than a composition ratio of Ge contained in the first source/drain layer SDL1. For example, the germanium composition ratio of SiGe contained in the first source/drain layer SDL1 may range from 10 at % to 30 at %, and the germanium composition ratio of SiGe contained in the second source/drain layer SDL2 may range from 40 at % to 60 at %.

The forming the source/drain region SD may further include injecting boron during or after the selective epitaxial growth (SEG) process. Thus, the source/drain region SD may include boron, and a boron concentration of the source/drain region SD may range from 10²⁰ atoms/cm³ to 10²¹ atoms/cm³.

During the selective epitaxial growth (SEG) process, the first source/drain layer SDL1 may be grown to be in contact with the first inner walls IS1 of the recess region RR. The first inner walls IS1 may be connected to the uppermost surfaces UPS of the active pattern AP, and the width (W1 of FIG. 6C) between the first inner walls IS1 along the first direction D1 may increase in a direction away from the uppermost surface UPS of the active pattern AP. At the contact point between each of the first inner walls IS1 of the recess region RR and the uppermost surface UPS of the active pattern AP, the angle AG between each of the first inner walls IS1 and the uppermost surface UPS of the active pattern AP may be the acute angle. Due to the first inner walls IS1, it is possible to inhibit end portions of the first source/drain layer SDL1 from being grown with a (111) plane. As a result, the source/drain regions SD may not include boron segregation caused by the (111) plane and defects caused by the boron segregation.

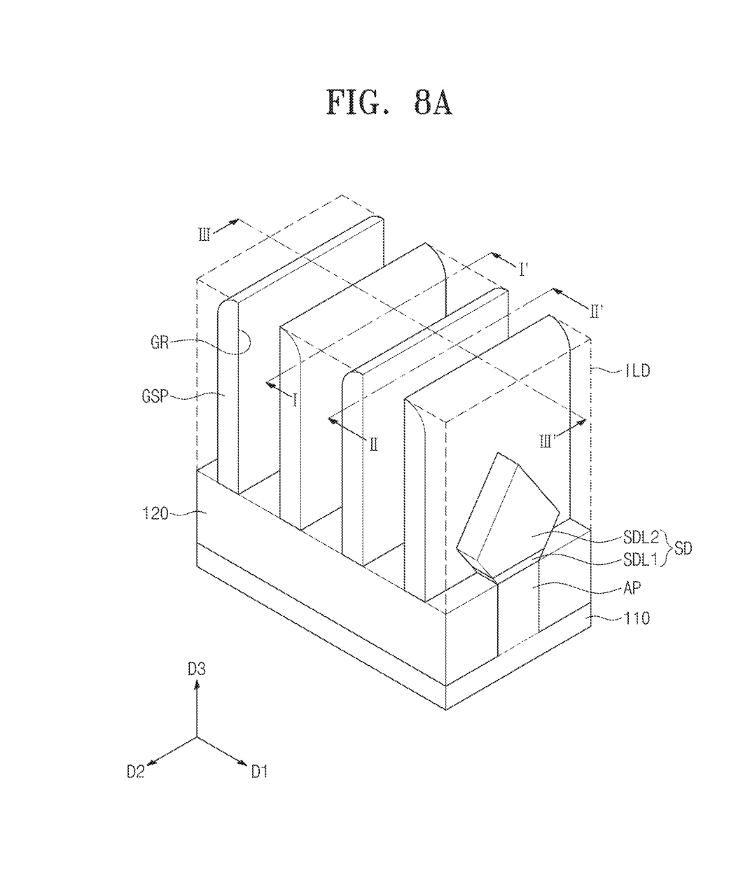

Referring to FIGS. 8A and 8B, a lower interlayer insulating layer ILD may be formed on the substrate 110 including the source/drain region SD. The lower interlayer insulating layer ILD may be formed to cover the source/drain region SD. The lower interlayer insulating layer ILD may include at least one of a silicon oxide layer, a silicon nitride layer or a low dielectric layer.

Gap regions GR may be formed between the gate spacers GSP by removing the gate mask patterns 134, the sacrificial gate patterns 132 and the etch stop patterns 130. The gap regions GR may expose a top surface and sidewalls of the active pattern AP. Forming the gap regions GR may include performing an etching process having an etch selectivity with respect to the gate spacers GSP, the lower interlayer insulating layer ILD and the etch stop patterns 130 to remove the sacrificial gate patterns 132. In addition, forming the gap regions GR may further include removing the etch stop patterns 130 to expose a top surface and sidewalls of the active pattern AP.

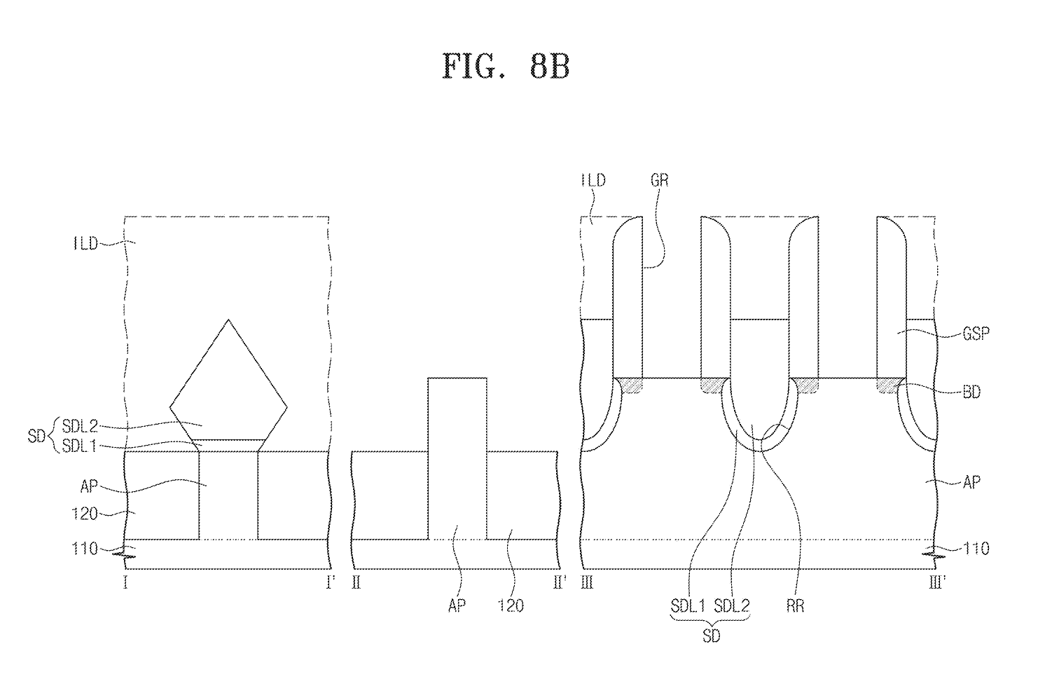

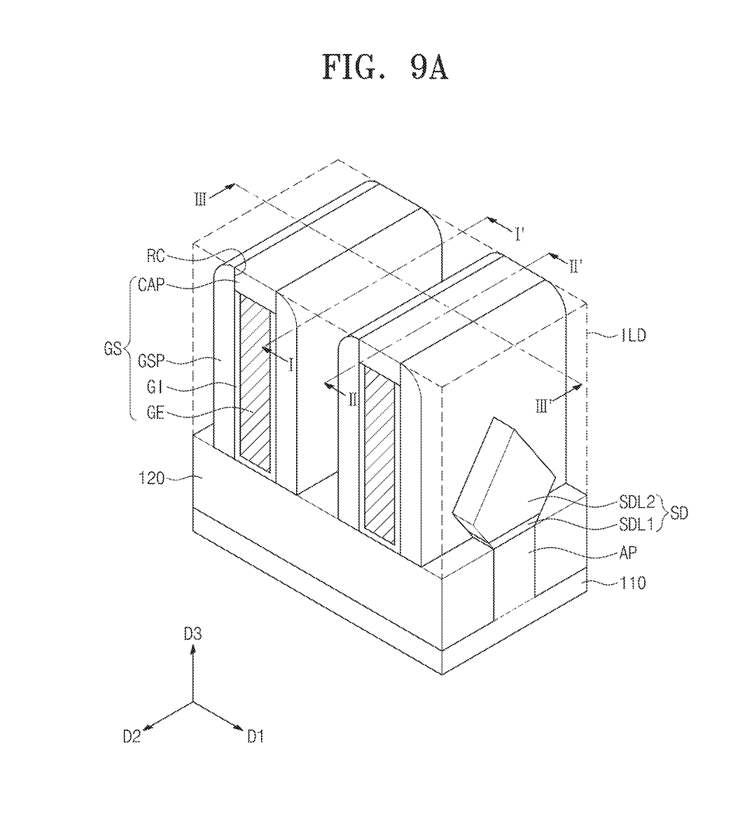

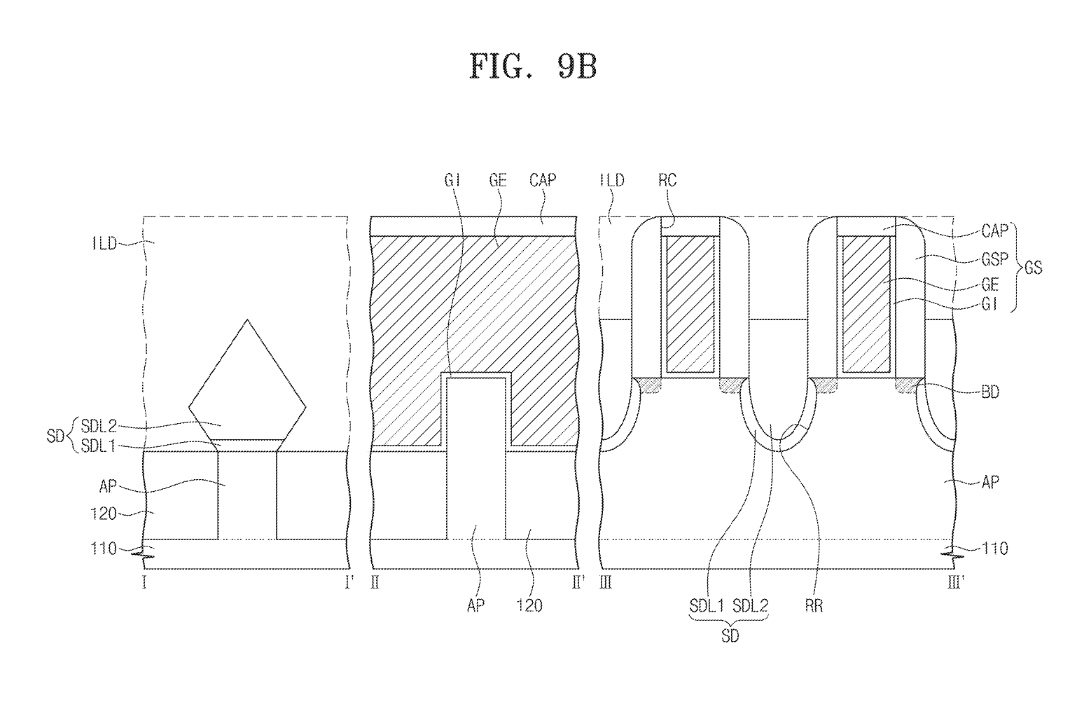

Referring to FIGS. 9A and 9B, a gate insulating pattern GI and a gate electrode GE may be formed to fill each of the gap regions GR. A gate insulating layer (not illustrated) may be formed on the substrate 110 including the gap regions GR to partially fill the gap regions GR. The gate insulating layer may conformally cover the top surface and the sidewalls of the active pattern AP exposed by the gap regions GR. The gate insulating layer may include at least one of high-k dielectric layers. For example, the gate insulating layer may include at least one of hafnium oxide, hafnium silicate, zirconium oxide, and zirconium silicate. However, embodiments of the inventive concepts are not limited thereto. The gate insulating layer may be formed by performing an atomic layer deposition (ALD) process. A gate layer (not illustrated) may be formed on the gate insulating layer to fill the rest portions of gap regions GR. The gate layer may include at least one of a conductive metallic nitride (for example, titanium nitride, or tantalum nitride) or a metal (for example, aluminum, tungsten, or copper). The gate insulating layer and the gate layer that are sequentially stacked may be planarized to form the gate insulating patterns GI and the gate electrodes GE. Top surfaces of the lower interlayer insulating layer ILD and the gate spacers GSP may be exposed by the planarization process. The gate insulating pattern GI may extend along a bottom surface of the gate electrode GE and may extend onto both sidewalls of the gate electrode GE so as to be interposed between the gate electrode GE and the gate spacers GSP.

Upper portions of the gate electrodes GE may be recessed until the gate electrodes GE reaches a desired thickness in the gap regions GR. During the recess process, upper portions of the gate insulating patterns GI not covered by the gate electrodes GE may be removed. Accordingly, recess regions RC may be defined in the gap regions GR. Capping patterns CAP may be formed in the recess region RC. Forming the capping patterns CAP may include forming a capping layer (not illustrated) filling the recess regions RC on the lower interlayer insulating layer ILD and planarizing the capping layer until the lower interlayer insulating layer ILD is exposed. The capping patterns CAP may include, for example, silicon nitride.

The gate electrode GE, the gate insulating pattern GI, the capping pattern CAP and a pair of the gate spacers GSP formed on both sidewalls of the gate electrode GE may be defined as a gate structure GS.

Although not illustrated, an upper interlayer insulating layer (not illustrated) may be formed on the substrate 110 including the gate structure GS. The upper interlayer insulating layer may include silicon oxide, silicon nitride and/or silicon oxynitride. First contact holes (not illustrated) exposing the source/drain regions SD may be formed to penetrate the upper interlayer insulating layer and the lower interlayer insulating layer ILD. By an etching process forming the first contact holes, as illustrated in FIGS. 1A and 1B, upper portions of the source/drain regions SD may be partially removed. Second contact holes (not illustrated) exposing the gate electrodes GE may be formed to penetrate the upper interlayer insulating layer and the lower interlayer insulating layer ILD. Next, first contact plugs (not illustrated) may be formed to fill the first contact holes and second contact plugs (not illustrated) may be formed to fill the second contact holes. Interconnection lines (not illustrated) connected to the first and second contact plugs may be formed on the upper interlayer insulating layer. The interconnection lines may be configured to apply voltages to the source/drain regions SD and the gate electrodes GE through the first and second contact plugs. The first and second contact plugs and the interconnection lines may include a conductive material.

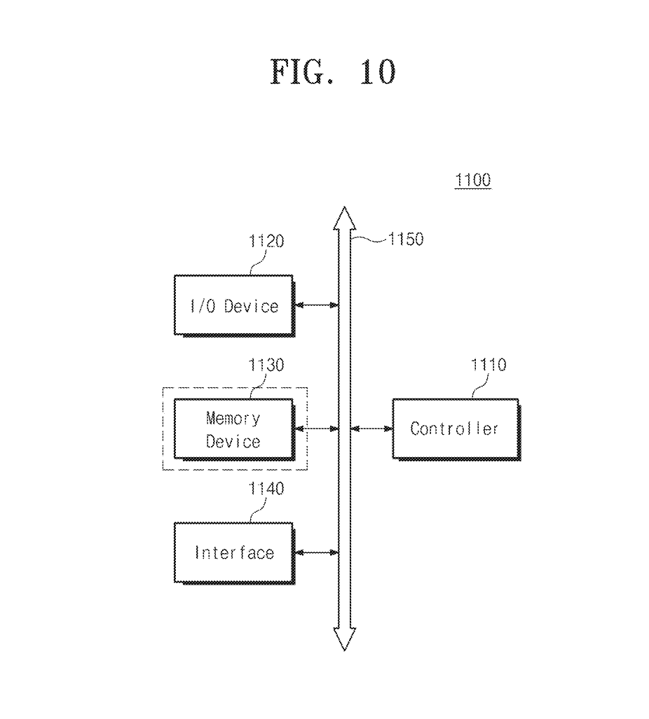

FIG. 10 is a schematic block diagram illustrating an electronic system including a semiconductor device in accordance with example embodiments of the inventive concept.

Referring to FIG. 10, an electronic system 1100 may include a controller 1110, an input/output (I/O) device 1120, a memory device 1130, an interface unit 1140, and a bus 1150. The controller 1110, the I/O device 1120, the memory device 1130 and the interface unit 1140 may be combined with one another through the bus 1150. The bus 1150 corresponds to a path through which electrical data are transmitted.

The controller 1110 may include at least one of a microprocessor, a digital signal process, a micro controller, or other logical devices performing a similar function to any one thereof. The I/O device 1120 may include a keypad, a keyboard and/or a display device. The memory device 1130 may store data and/or commands. The memory device 1130 may include a nonvolatile memory device (e.g., a flash memory device, a phase-change memory device, and/or a magnetic memory device). In addition, the memory device 1130 may further include a volatile memory device. In this case, the memory device 1130 may include a SRAM including the semiconductor device in accordance with exemplary embodiments of the inventive concept. The memory device 1130 may be omitted depending on an application of the electronic system 1100 or an electronic product implemented with the electronic system 1100. The interface unit 1140 may perform a function of transmitting data to a communication network or a function of receiving data from the communication network. The interface unit 1140 may operate by cable or wireless. For instance, the interface unit 1140 may include an antenna or a wired/wireless transceiver. The semiconductor device in accordance with exemplary embodiments of the inventive concept may be provided to a part of the controller 1110 or the I/O device 1120. Although not illustrated, the electronic system 1100 may further include a fast DRAM device and/or a fast SRAM device as an operating memory device for improving an operation of the controller 1110.

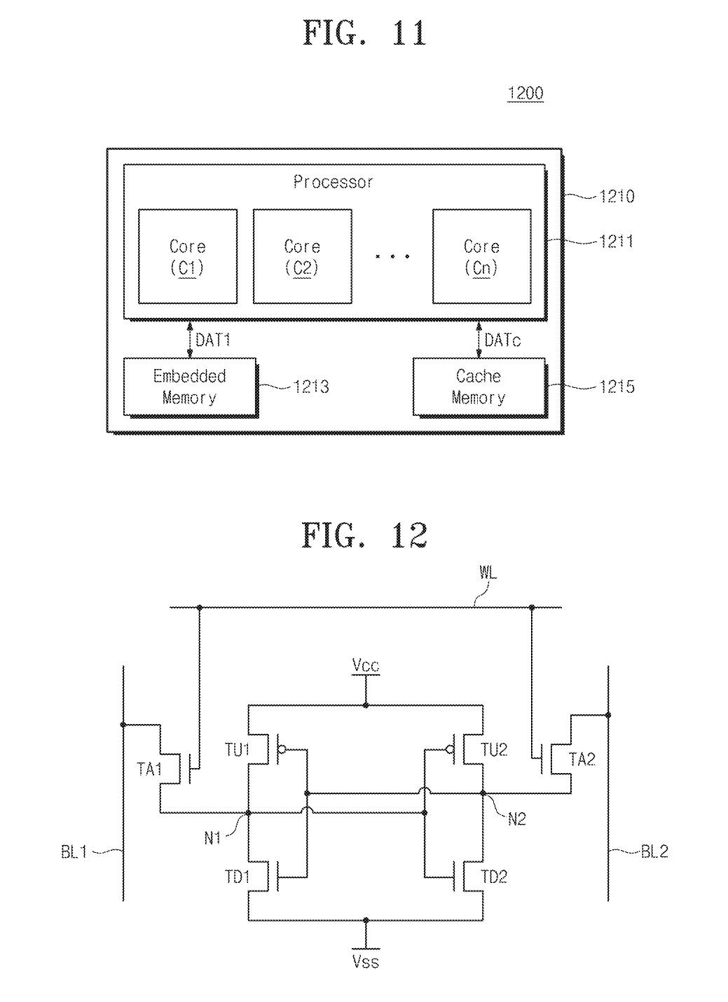

FIG. 11 is a schematic block diagram illustrating an electronic device including a semiconductor device in accordance with example embodiments of the inventive concept.

Referring to FIG. 11, an electronic device 1200 may include a semiconductor chip 1210. The semiconductor chip 1210 may include a processor 1211, an embedded memory 1213 and a cache memory 1215.

The processor 1211 may include one or more processor cores C1 to Cn. The processor cores C1 to Cn may process data and signals. The processor cores C1 to Cn may include the semiconductor device in accordance with example embodiments of the inventive concept.

The electronic device 1200 may perform a specific function using the processed data and signals. The processor 1211 may be an application processor.

The embedded memory 1213 may exchange first data DATA1 with the processor 1211. The first data DATA1 is data processed or to be processed by the one or more processor cores C1 to Cn. The embedded memory 1213 may manage the first data DATA1. For example, the embedded memory 1213 may buffer the first data DATA1. The embedded memory 1213 may operate as a buffer memory or a working memory.

According to an example embodiment of the inventive concept, the electronic device 1200 may be applied to a wearable electronic device. The wearable electronic device may perform a function that needs a small quantity of operations rather than a function that needs a large quantity of operations. Thus, in the case that the electronic device 1200 is applied to the wearable electronic device, the embedded memory 1213 may not have a large buffer capacity.

The embedded memory 1213 may be a SRAM. The SRAM may operate at a speed higher than the DRAM. If the SRAM is embedded in the semiconductor chip 1210, the electronic device 1200 which has a small size and operates at a high speed may be embodied. Further, if the SRAM is embedded in the semiconductor chip 1210, consumption of active power of the electronic device 1200 may be reduced. The SRAM may include the semiconductor device in accordance with exemplary embodiments of the inventive concept.

The cache memory 1215 may be mounted on the semiconductor chip 1210 together with the one or more processor cores C1 to Cn. The cache memory 1215 may store cache data DATc. The cache data DATc may be data used by the one or more processor cores C1 to Cn. The cache memory 1215 may have a small storage capacity but may operate at a very high speed. The cache memory 1215 may include a SRAM including the semiconductor device in accordance with exemplary embodiments of the inventive concept. In the case that the cache memory 1215 is used, the number of times the processor 1211 accesses to the embedded memory 1213 may be reduced and the time taken for the process 1211 to access to the embedded memory 1213 may also be reduced. Thus, in the case that the cache memory 1215 is used, an operating speed of the electronic device 1200 may increase.

In FIG. 11, to help understanding, the cache memory 1215 is separated from the processor 1211. However, the cache memory 1215 may be configured to be included in the processor 1211. FIG. 11 is not to limit the range of protection of a technical spirit of the inventive concept.

The processor 1211, the embedded memory 1213 and the cache memory 1215 may transmit data based on various interface regulations. For instance, the processor 1211, the embedded memory 1213 and the cache memory 1215 may transmit data based on one or more interface regulations among a universal serial bus (USB), a small computer system interface (SCSI), a multimedia card (MMC) interface, a peripheral component interconnect (PCI) express, a advanced technology attachment (ATA), a serial ATA (SATA), a parallel ATA (PATA), a serial attached SCSI (SAS), an integrated drive electronics (IDE), and a universal flash storage (UFS).

FIG. 12 is an equivalent circuit of a SRAM cell in accordance with example embodiments of the inventive concept. The SRAM cell may be embodied by the semiconductor device in accordance with example embodiments of the inventive concept. The SRAM cell may be applied to the embedded memory 1213 and/or the cache memory 1215 described in FIG. 11.

Referring to FIG. 12, the SRAM cell may include a first pull-up transistor TU1, a first pull-down transistor TD1, a second pull-up transistor TU2, a second pull-down transistor TD2, a first access transistor TA1 and a second access transistor TA2. The first and second pull-up transistors TU1 and TU2 may be PMOS transistors while the first and second pull-down transistors TD1 and TD2 and the first and second access transistors TA1 and TA2 may be NMOS transistors.

A first source/drain of the first pull-up transistor TU1 and a first source/drain of the first pull-down transistor TD1 may be connected to a first node N1. A second source/drain of the first pull-up transistor TU1 may be connected to a power supply line Vcc and a second source/drain of the first pull-down transistor TD1 may be connected to a ground line Vss. A gate of the first pull-up transistor TU1 and a gate of the first pull-down transistor TD1 may be electrically connected to each other. The first pull-up transistor TU1 and the first pull-down transistor TD1 may constitute a first inverter. Gates of the first pull-up transistor TU1 and the first pull-down transistor TD1 may correspond to an input terminal of the first inverter and the first node N1 may correspond to an output terminal of the first inverter.

A first source/drain of the second pull-up transistor TU2 and a first source/drain of the second pull-down transistor TD2 may be connected to a second node N2. A second source/drain of the second pull-up transistor TU2 may be connected to the power supply line Vcc and a second source/drain of the second pull-down transistor TD2 may be connected to the ground line Vss. A gate of the second pull-up transistor TU2 and a gate of the second pull-down transistor TD2 may be electrically connected to each other. The second pull-up transistor TU2 and the second pull-down transistor TD2 may constitute a second inverter. Gates of the second pull-up transistor TU2 and the second pull-down transistor TD2 may correspond to an input terminal of the second inverter and the second node N2 may correspond to an output terminal of the second inverter.

The first and second inverters may be combined with each other to constitute a latch structure. That is, the gates of the first pull-up and pull-down transistors TU1 and TD1 may be electrically connected to the second node N2 and the gates of the second pull-up and pull-down transistors TU2 and TD2 may be electrically connected to the first node N1. A first source/drain of the first access transistor TA1 may be connected to the first node N1 and a second source/drain of the first access transistor TA1 may be connected to a first bit line BL1. A first source/drain of the second access transistor TA2 may be connected to the second node N2 and a second source/drain of the second access transistor TA2 may be connected to a second bit line BL2. Gates of the first and second access transistors TA1 and TA2 may be electrically connected to a word line WL. As a result, the SRAM in accordance with example embodiments of the inventive concept may be embodied.

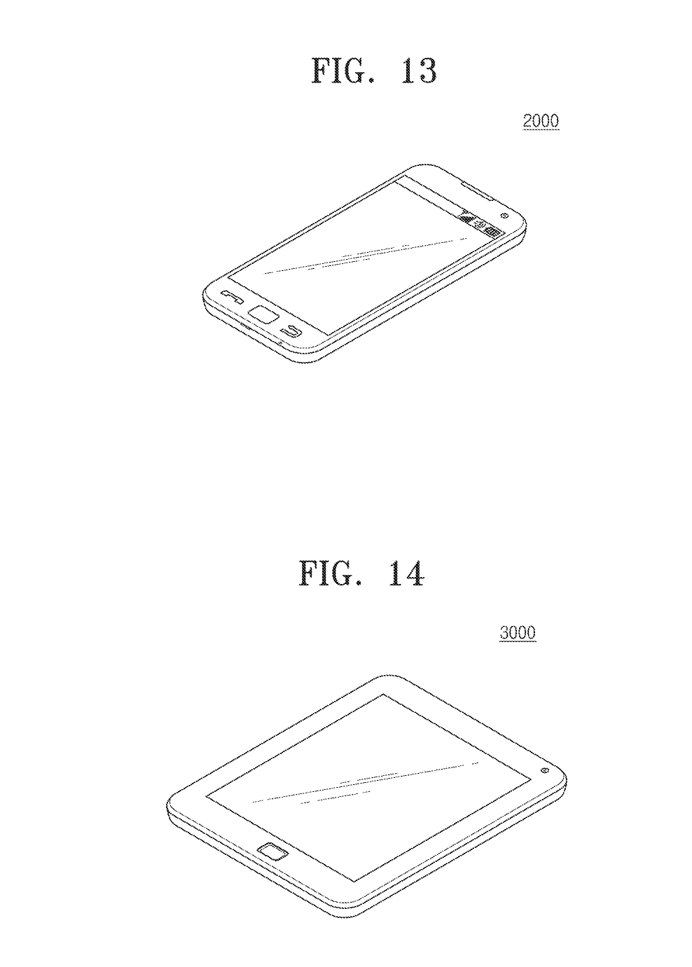

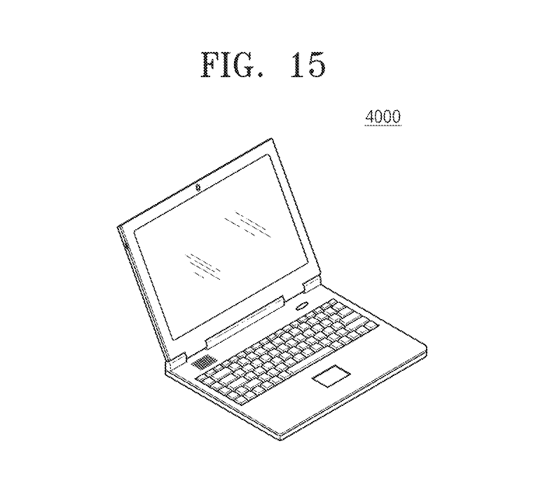

FIGS. 13 through 15 illustrate examples of a multimedia device including a semiconductor device in accordance with example embodiments of the inventive concept. The electronic system 1100 of FIG. 10 and/or the electronic device 1200 of FIG. 11 may be applied to a mobile phone or a smart phone 2000 illustrated in FIG. 13, a tablet or a smart tablet 3000 illustrated in FIG. 14 and a notebook computer 4000 illustrated in FIG. 15.

In the semiconductor device according to an embodiment of the inventive concepts, the recess region of the active pattern may include inner walls connected to the uppermost surface of the active pattern. The width between the inner walls in one direction may increase as a depth from the uppermost surface of the active pattern increases. These inner walls may inhibit end portions of the first source/drain layer conformally formed in the recess region from being grown with the (111) plane. Thus, the source/drain regions may not include boron segregation caused by the (111) plane, and defects caused by the boron segregation. As a result, reliability of the semiconductor device may be improved.

Although a few embodiments of the present inventive concept have been shown and described, it will be appreciated by those skilled in the art that changes may be made in these embodiments without departing from the principles and spirit of the inventive concept, the scope of which is defined in the appended claims and their equivalents. Therefore, the above-disclosed subject matter is to be considered illustrative, and not restrictive.

What is claimed is:

1. A semiconductor device comprising:
a substrate;
an active pattern protruding from the substrate and extending in a first direction;
first and second gate electrodes intersecting the active pattern in a second direction intersecting the first direction, the first and second gate electrodes spaced apart from each other along the first direction; and
a source/drain region disposed on the active pattern between the first and second gate electrodes,
wherein the source/drain region comprises:
a first part adjacent to an uppermost surface of the active pattern, the first part provided at a level lower than the uppermost surface of the active pattern; and
a second part being in contact with the first part, the second part disposed under the first part,
wherein a width of the first part along the first direction decreases in a direction away from the substrate, and
wherein a width of the second part along the first direction increases in a direction away from the substrate.

2. The semiconductor device of claim 1, wherein each of the first part and the second part has a maximum thickness in a direction perpendicular to a top surface of the substrate, and
wherein the maximum thickness of the first part ranges from about 5% to about 15% of the sum of the maximum thicknesses of the first and second parts.

3. The semiconductor device of claim 2, wherein the maximum thickness of the first part ranges from about 2 nm to about 8 nm.

4. The semiconductor device of claim 1, wherein an angle between a sidewall of the first part and the uppermost surface of the active pattern is an acute angle at a contact point between the sidewall of the first part and the uppermost surface of the active pattern.

5. The semiconductor device of claim 4, wherein the angle between the sidewall of the first part and the uppermost surface of the active pattern ranges from about 40 degrees to about 60 degrees.

6. The semiconductor device of claim 1, wherein the second part has a rounded bottom surface having a U-shape.

7. The semiconductor device of claim 1, wherein the source/drain region comprises silicon-germanium (SiGe) doped with boron.

8. The semiconductor device of claim 1, wherein the active pattern comprises: a boron-doped region comprising boron, and
wherein the boron-doped region is adjacent to the uppermost surface of the active pattern and is in contact with the first part.

9. The semiconductor device of claim 8, wherein a boron concentration of the boron-doped region ranges from about 10¹⁴ atoms/cm³ to about 10¹⁵ atoms/cm³.

10. The semiconductor device of claim 8, wherein each of the boron-doped region and the first part has a maximum thickness in a direction perpendicular to a top surface of the substrate, and
wherein the maximum thickness of the first part is equal to or greater than the maximum thickness of the boron-doped region.

11. The semiconductor device of claim 8, wherein the boron-doped region comprises a plurality of boron-doped regions, and
wherein one of the boron-doped regions is located between the source/drain region and the first gate electrode, and another of the boron-doped regions is located between the source/drain region and the second gate electrode.

12. The semiconductor device of claim 8, wherein a width of the boron doping region increases in a direction away from the substrate.

13. A semiconductor device comprising:
a substrate;
an active pattern protruding from the substrate, the active pattern extending in a first direction, and the active pattern having a recess region recessed from an uppermost surface of the active pattern;
first and second gate electrodes intersecting the active pattern in a second direction intersecting the first direction, the first and second gate electrodes spaced apart from each other with the recess region interposed therebetween; and
a source/drain region filling the recess region,
wherein the recess region comprises:
a bottom surface;
a pair of first inner walls connected to the uppermost surface of the active pattern, wherein a width between the pair of first inner walls along the first direction increases in a direction away from the uppermost surface of the active pattern; and
a pair of second inner walls connected between the bottom surface and the pair of first inner walls, wherein a width between the pair of second inner walls along the first direction decreases in a direction away from the uppermost surface of the active pattern.

14. The semiconductor device of claim 13, wherein the bottom surface has a rounded shape.

15. The semiconductor device of claim 13, wherein an angle between each of the first inner walls of the recess region and the uppermost surface of the active pattern is an acute angle at a contact point between each of the first inner walls of the recess region and the uppermost surface of the active pattern.

16. The semiconductor device of claim 15, wherein the angle between each of the first inner walls of the recess region and the uppermost surface of the active pattern ranges from about 40 degrees to about 60 degrees.

17. The semiconductor device of claim 13, wherein the source/drain region comprises:
a first source/drain layer conformally covering the first inner walls, the second inner walls and the bottom surface of the recess region; and
a second source/drain layer disposed on the first source/drain layer to fill the recess region,
wherein the source/drain region comprises silicon-germanium (SiGe) doped with boron, and
wherein a composition ratio of germanium (Ge) contained in the second source/drain layer is greater than a composition ratio of Ge contained in the first source/drain layer.

18. The semiconductor device of claim 17, wherein the first source/drain layer has a U-shape when viewed from a cross-sectional view.

19. The semiconductor device of claim 13, wherein the active pattern comprises: a pair of boron-doped regions,
wherein one of the pair of boron-doped regions is provided between the first gate electrode and one of the pair of first inner walls, and
wherein the other of the pair of the boron-doped regions is provided between the second gate electrode and the other of the pair of first inner walls.

20. The semiconductor device of claim 19, wherein each of the boron-doped regions has a width in the first direction, and
wherein the width of each of the boron-doped regions increases in a direction away from the substrate.
